(19) United States
(12) Patent Application Publication
(10) Pub. No.: US 2015/0111394 A1
(43) Pub. Date: Apr. 23, 2015

(54) MECHANISMS FOR FORMING UNIFORM FILM ON SEMICONDUCTOR SUBSTRATE

(71) Applicant: Taiwan Semiconductor Manufacturing Co., Ltd., Hsin-Chu (TW)

(72) Inventors: Chun-Hao HSU, New Taipei City (TW); Yu-Li CHANG, Toufen Township, Miaoli County (TW); Chia-I SHEN, Hsinchu City (TW)

(73) Assignee: Taiwan Semiconductor Manufacturing Co., Ltd., Hsin-Chu (TW)

(21) Appl. No.: 14/060,926

(22) Filed: Oct. 23, 2013

(51) Int. Cl. H01L 21/02

(52) U.S. Cl. CPC H01L 21/0214; H01L 21/02274
USPC 438/786; 118/723 R

(57) ABSTRACT

Embodiments of mechanisms for forming a film deposition tool are provided. The film deposition tool includes a plasma source and a substrate processing region connected to the plasma source. The film deposition tool also includes a pedestal for supporting a substrate in the substrate processing region, wherein the substrate is prepared to be deposited with a film. The film deposition tool further includes electrodes embedded in the pedestal and separated from each other. The film deposition tool also includes a direct current bias system having variable voltage sources. The variable voltage sources are electrically connected to the electrodes, respectively, for providing direct current voltages to the electrodes independently.

### BACKGROUND

Semiconductor device geometries have dramatically decreased in size since their introduction several decades ago. Modern semiconductor fabrication equipment routinely produces devices with 45 nm, 32 nm, and 28 nm feature sizes, and new equipment is developed and implemented to make devices with even smaller geometries. The decreased feature sizes result in structural features on the device having decreased spatial dimensions.

The widths of gaps (or trenches) on the device narrow, and therefore the aspect ratio of gap depth to its width is high, which results in a difficulty in filling the gaps with a material (e.g. a dielectric material) deposited on the device. The deposited material is prone to clog at the top of the gaps, which produces voids in the gaps.

### BRIEF DESCRIPTION OF THE DRAWINGS

For a more complete understanding of the embodiments, and the advantages thereof, reference is now made to the following descriptions taken in conjunction with the accompanying drawings.

FIG. 1A is a cross-sectional view of a film deposition tool, in accordance with some embodiments.

FIG. 1B is a cross-sectional and perspective view of a portion of the showerhead of FIG. 1A, in accordance with some embodiments.

FIG. 1C is a cross-sectional view of a substrate and a silicon oxide film, in accordance with some embodiments.

FIG. 1D is a cross-sectional view of a substrate and a planarized silicon oxide film, in accordance with some embodiments.

FIG. 2A is a cross-sectional view of a film deposition tool, in accordance with some embodiments.

FIG. 2B is a cross-sectional enlarged view of a portion of the showerhead of FIG. 2A, in accordance with some embodiments.

FIG. 2C is a top view of the electrodes of FIG. 2A, in accordance with some embodiments.

FIG. 2D is a cross-sectional view of a substrate and a silicon oxide film, in accordance with some embodiments.

FIG. 2E is a cross-sectional view of a substrate and a planarized silicon oxide film, in accordance with some embodiments.

FIG. 3A is a top view of electrodes of a film deposition tool, in accordance with some embodiments.

FIG. 3B is a cross-sectional view of a film deposition tool with the electrodes of FIG. 3A, in accordance with some embodiments.

FIG. 4 is a top view of electrodes of a film deposition tool, in accordance with some embodiments.

### DETAILED DESCRIPTION

The making and using of the embodiments of the disclosure are discussed in detail below. It should be appreciated, however, that the embodiments can be embodied in a wide variety of specific contexts. The specific embodiments discussed are merely illustrative, and do not limit the scope of the disclosure.

It is to be understood that the following disclosure provides many different embodiments, or examples, for implementing different features of the disclosure. Specific examples of components and arrangements are described below to simplify the present disclosure. These are, of course, merely examples and are not intended to be limiting. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows include embodiments in which the first and second features are formed in direct contact, and may also include embodiments in which additional features may be formed between the first and second features, such that the first and second features may not be in direct contact.

Some variations of the embodiments are described. Throughout the various views and illustrative embodiments, like reference numbers are used to designate like elements.

In some embodiments, various methods are developed to avoid having a material (e.g. a dielectric material) clogging the top of a gap, or to “heal” the void or seam that has been formed. One method includes forming highly flowable precursor materials (in a liquid phase) to a spinning substrate surface. These flowable precursors can flow into and fill very small substrate gaps without forming voids. The method is described in detail below.

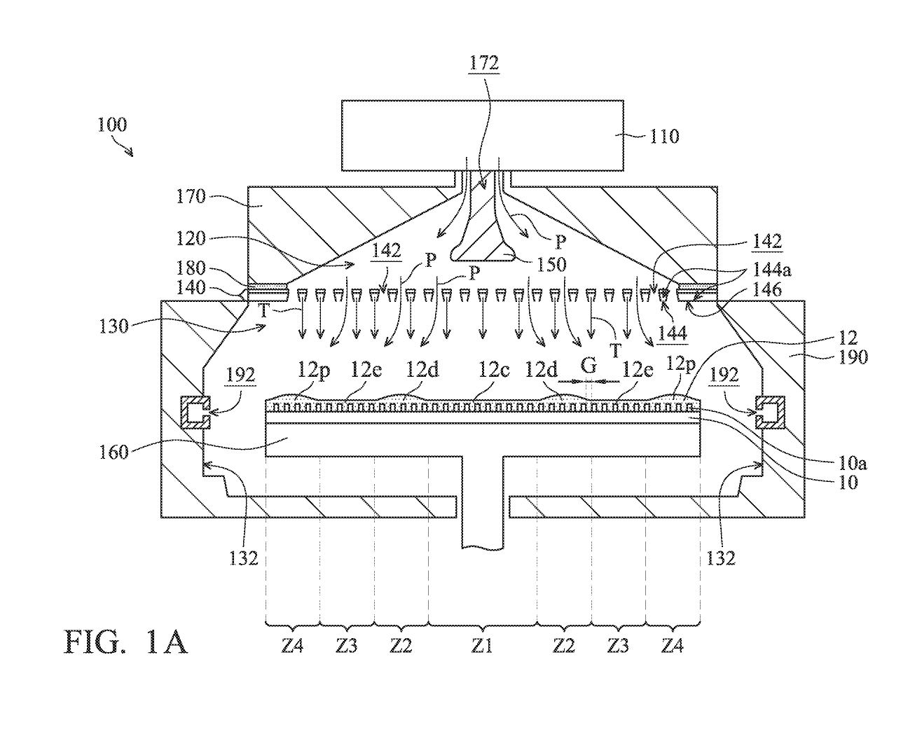

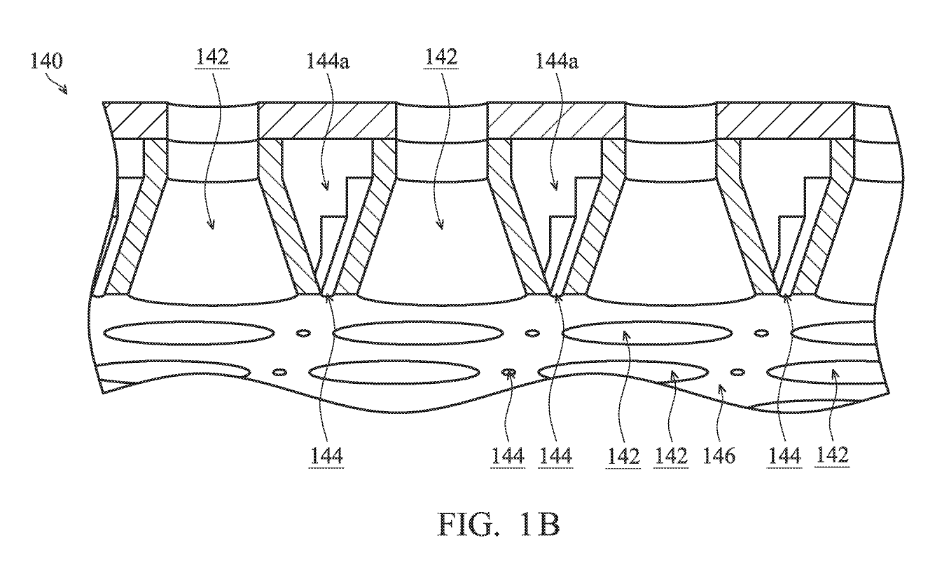

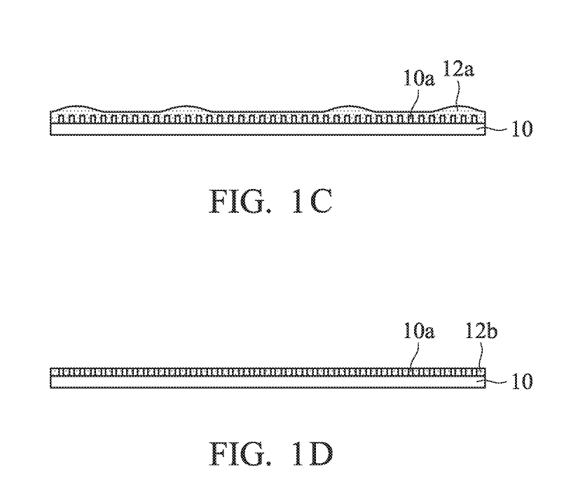

FIG. 1A is a cross-sectional view of a film deposition tool, in accordance with some embodiments. As shown in FIG. 1A, a film deposition tool 100 includes a plasma source 110, a chamber plasma region 120, a substrate processing region 130, a showerhead (also referred to as a perforated portion) 140, a diffuser 150 and a pedestal 160.

The plasma source 110 is positioned on a lid (or a conductive top portion) 170 to connect an inlet opening 172 of the lid 170 so as to connect the chamber plasma region 120 in the lid 170. The plasma source 110 is configured to provide plasma to the chamber plasma region 120. The flow directions of the plasma are shown as arrows P in FIG. 1A. The plasma source 110 includes, for example, a remote plasma system (RPS). In some embodiments, the plasma is formed from ammonia (NH₃) and oxygen (O₂). In some other embodiments, the plasma is formed from one or more of the following: ozone (O₃), N₂O, NO, NO₂, NH₃, N₂H₄, silane and disilane.

The diffuser 150 is disposed in the chamber plasma region 120 close to the inlet opening 172 to diffuse the plasma from the plasma source 110 uniformly. The lid 170 may be above the showerhead 140. An insulating ring 180 may be disposed between the lid 170 and the showerhead 140 to insulate the lid 170 from the showerhead 140.

The showerhead 140 is between the chamber plasma region 120 and the substrate processing region 130 beneath the showerhead 140. The showerhead 140 allows the plasma to travel from the chamber plasma region 120 into the substrate processing region 130 via through holes 142 of the showerhead 140 so as to limit the flow of the plasma. Therefore, the showerhead 140 is able to prevent the plasma present in the chamber plasma region 120 from directly exciting gases in the substrate processing region 130.

FIG. 1B is a cross-sectional and perspective view of a portion of the showerhead 140 of FIG. 1A, in accordance with some embodiments. As shown in FIGS. 1A and 1B, the showerhead 140 has the through holes 142 and a hollow volume 144a separated from the through holes 142. The showerhead 140 has (small) holes 144 extending from a lower surface 146 of the showerhead 140 to the hollow volume 144a and connecting the substrate processing region 130.

The hollow volume 144a may be filled with a precursor in the form of a vapor or gas (such as a silicon-containing precursor), and the precursor may pass through the holes 144 into the substrate processing region 130. The silicon-containing precursor may include silyl-amines such as N(SiH₃)₃ (i.e., TSA), HN(SiH₃)₂ (i.e., DSA), H₂N(SiH₃), or other silyl-amines. The flow directions of the precursor are shown as arrows T in FIG. 1A.

The pedestal 160 is positioned in the substrate processing region 130 to support a substrate 10 prepared to be deposited. In the substrate processing region 130, the flows of the plasmas (e.g. the nitrogen plasma and the oxygen plasma) from the chamber plasma region 120 mix and react with the precursor (e.g. the silicon-containing precursor) to deposit a silicon, oxygen, and nitrogen-containing film 12 on the substrate 10.

The silicon, oxygen, and nitrogen-containing film 12 has flowable characteristics, which allows the silicon, oxygen, and nitrogen-containing film 12 to flow into narrow gaps, trenches or other structures (not shown) on the deposition surface of the substrate 10. The silicon, oxygen, and nitrogen-containing film 12 may have a polysilazane network. The deposition process includes, for example, a flowable chemical vapor deposition (FCVD) process. In some embodiments, the pedestal 160 spins during the deposition process.

In some embodiments, there are fin structures 10a on the top surface 10 of the substrate 10, and the fin structures 10a are formed for forming fin field effect transistors (FinFETs). The fin structures 10a are spaced from each other, and the silicon, oxygen, and nitrogen-containing film 12 covers the fin structures 10a and fills the gaps G between the fin structures 10a.

Afterwards, the silicon, oxygen, and nitrogen-containing film 12 may be converted into a silicon oxide film 12a, as shown in FIG. 1C. The conversion process may include curing the silicon, oxygen, and nitrogen-containing film 12 in an oxygen-containing atmosphere and annealing the silicon, oxygen, and nitrogen-containing film 12 in an oxygen-containing atmosphere. Then, the silicon oxide film 12a may be planarized into a planarized silicon oxide film 12b (as shown in FIG. 1D) by using, for example, a chemical-mechanical polishing (CMP) process.

As shown in FIG. 1A, the pedestal 160 may be divided into four zones Z1, Z2, Z3 and Z4 in the radius direction, and the diffuser 150 is right above the zone Z1. The center portion 12c of the silicon, oxygen, and nitrogen-containing film 12 is above the zone Z1 and is shielded from a portion of the plasma by the diffuser 150. Therefore, the center portion 12c is thinner than the portion 12d of the silicon, oxygen, and nitrogen-containing film 12 above the zone Z2 and surrounding the center portion 12c.

In some embodiments, the plasma is sucked into suction holes 192 of a chamber wall 190 surrounding the substrate processing region 130. The suction holes 192 are connected to a suction pump (not shown). Since the plasma flows toward the suction holes 192, the peripheral portion 12p of the silicon, oxygen, and nitrogen-containing film 12 in the zone Z4 is thicker than the portion 12e of the silicon, oxygen, and nitrogen-containing film 12 in the zone Z3.

Therefore, the uniformity of the thickness of the silicon, oxygen, and nitrogen-containing film 12 is low, which results in a large stress in the subsequent processes (e.g. the annealing process and the CMP process). The large stress may damage the fin structures 10a (hereinafter referred to as a stress issue), and therefore it is desirable to find alternative mechanisms for controlling the deposition process to form a uniform film.

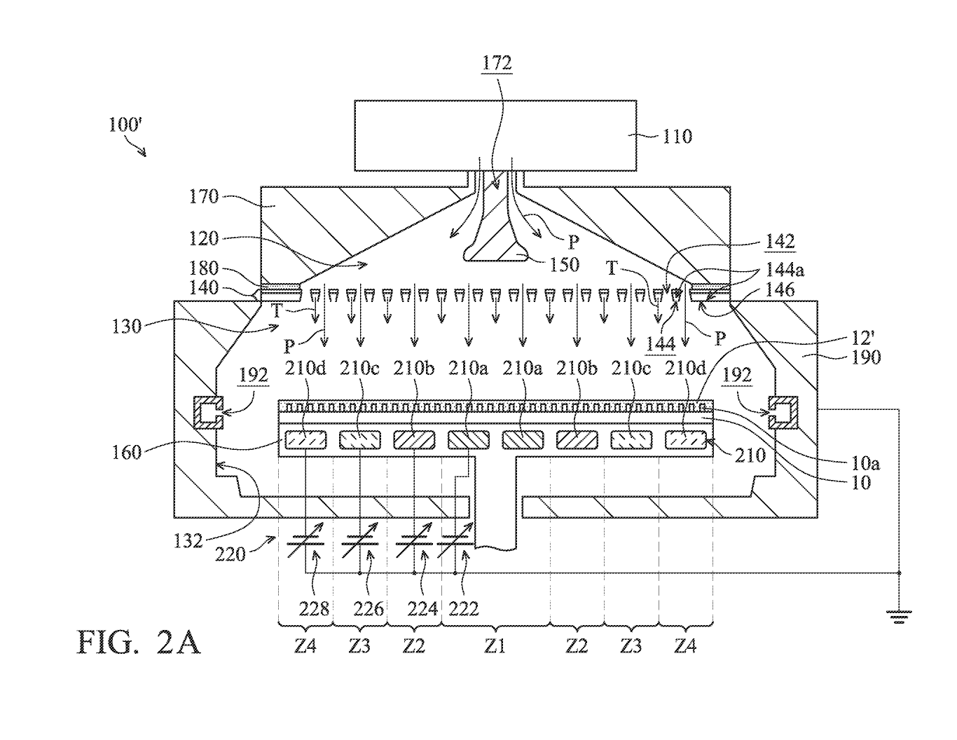

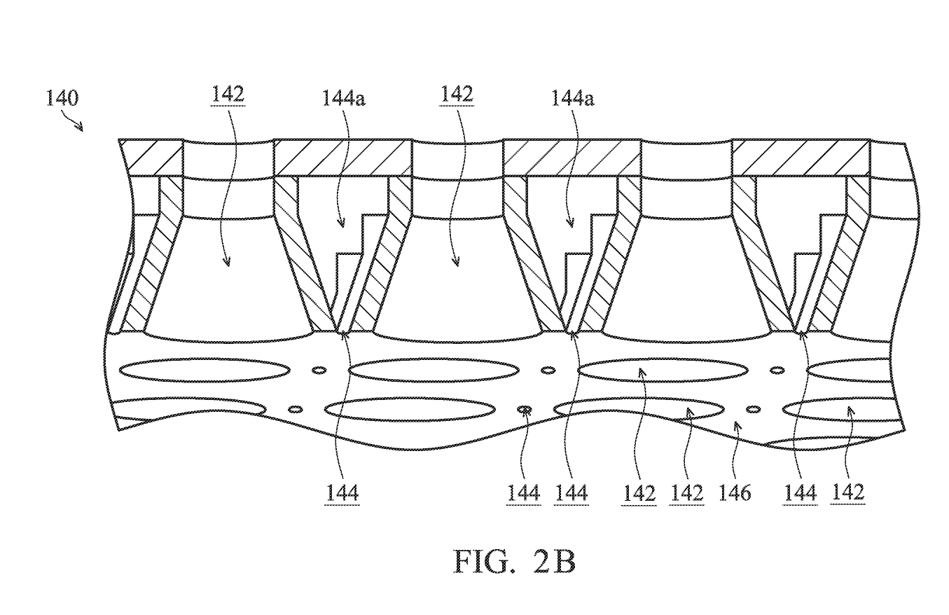

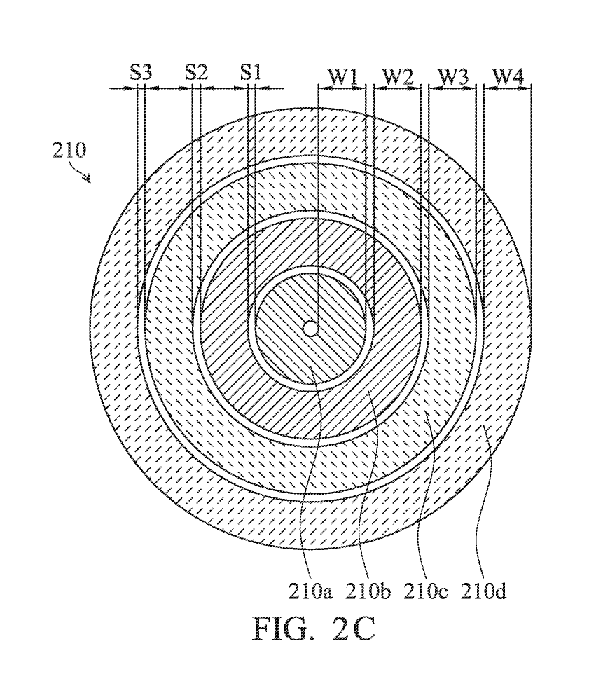

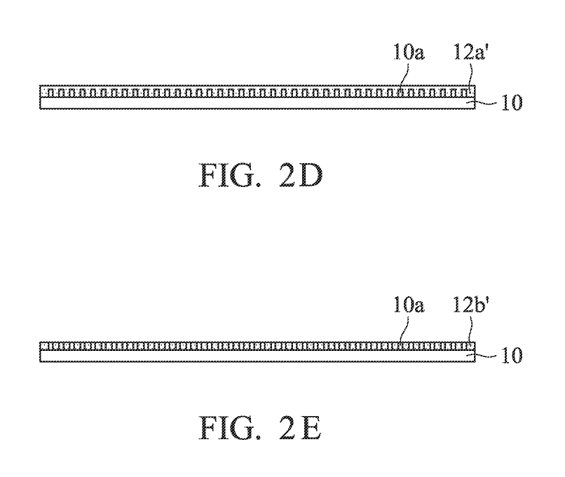

FIG. 2A is a cross-sectional view of a film deposition tool, in accordance with some embodiments. FIG. 2B is a cross-sectional enlarged view of a portion of the showerhead of FIG. 2A, in accordance with some embodiments. As shown in FIGS. 2A and 2B, a film deposition tool 100′ includes a plasma source 110, a chamber plasma region 120, a substrate processing region 130, a showerhead 140, a pedestal 160, electrodes 210 and a direct current bias system (DC bias system) 220. The film deposition tool 100′ may optionally include a diffuser 150. The film deposition tool 100′ includes, for example, a flowable chemical vapor deposition (FCVD) tool or any other chemical vapor deposition tools using a plasma.

The electrodes 210 are embedded in the pedestal 160 and are separated from each other by the pedestal 160, in accordance with some embodiments. The electrodes 210 are configured to provide different bias voltage to the substrate 10 above different zones of the pedestal 160 so as to control the deposition rates in different zones. The electrodes 210 may include a first electrode 210a, a second electrode 210b, a third electrode 210c and a fourth electrode 210d in the zones Z1, Z2, Z3 and Z4, respectively. In some embodiments, the first electrode 210a is under (or right under) the diffuser 150.

FIG. 2C is a top view of the electrodes 210 of FIG. 2A, in accordance with some embodiments. As shown in FIG. 2C, the first electrode 210a, the second electrode 210b, the third electrode 210c and the fourth electrode 210d are formed in a ring shape, in accordance with some embodiments. For example, the first electrode 210a, the second electrode 210b, the third electrode 210c and the fourth electrode 210d are arranged in a series of concentric rings. The first electrode 210a, the second electrode 210b, the third electrode 210c and the fourth electrode 210d may be continuous ring structures. In some other embodiments, the first electrode 210a is in a circular shape.

The DC bias system 220 is configured to provide different voltages to the electrodes 210 so as to provide different bias voltage to the substrate 210 in different zones independently. The DC bias system 220 may have variable voltage sources 222, 224, 226 and 228. The variable voltage sources 222, 224, 226 and 228 are coupled to (or electrically connected to) the first electrode 210a, the second electrode 210b, the third electrode 210c and the fourth electrode 210d, respectively.

Therefore, the electrodes 222, 224, 226 and 228 are provided with DC voltages independently by the variable voltage sources 222, 224, 226 and 228. The DC bias system 220 and a chamber wall 190 surrounding the substrate processing region 130 may be grounded together. The DC voltages provided by the variable voltage sources 222, 224, 226 and 228 may range from about −10 V to about 10 V.

In some embodiments, the plasma includes positively ionized gases (e.g. NHₓ* including, for example, NH₄⁺, NH₂⁺, NH⁺, etc.), and the variable voltage sources 222 and 226 provide a negative voltage to the first and the third electrodes 210a and 210c to attract the positively ionized gases to the portions of the substrate 10 above the zones Z1 and Z3. Therefore, the deposition rate over the portions of the substrate 10 above the zones Z1 and Z3 is increased. Thereby, a silicon, oxygen, and nitrogen-containing film 12′ formed on the substrate 10 has a relatively uniform thickness compared to that of the silicon, oxygen, and nitrogen-containing film 12 of FIG. 1A.

Since the present embodiments may provide different bias voltages to the substrate 10 above different zones of the pedestal 160, the silicon, oxygen, and nitrogen-containing film 12′ may have a uniform thickness. Therefore, the uniformity of the silicon, oxygen, and nitrogen-containing film 12′ is increased, which avoids the stress issue in the subsequent processes (e.g. the annealing process and the CMP process). Thereby, the yield is improved.

In some embodiments, the plasma includes positively ionized gases, and the variable voltage sources 224 and 228 provide a positive voltage to the second and the fourth electrodes 210b and 210d to repel the positively ionized gases away from the portions of the substrate 10 above the zones Z2 and Z4. Therefore, the deposition rate of the silicon, oxygen, and nitrogen-containing film 12′ above the zones Z2 and Z4 is decreased. Thereby, the silicon, oxygen, and nitrogen-containing film 12′ formed on the substrate 10 has a uniform thickness.

In some embodiments, the plasma includes positively ionized gases. The variable voltage sources 224 and 228 may provide a positive voltage to the second and the fourth electrodes 210b and 210d, and the variable voltage sources 222 and 226 may provide a negative voltage to the first and the third electrodes 210a and 210c according to requirements.

In some embodiments, the plasma includes negatively ionized gases, and the variable voltage sources 222 and 226 provide a positive voltage to the first and the third electrodes 210a and 210c to attract the negatively ionized gases to the portions of the substrate 10 above the zones Z1 and Z3. Therefore, the deposition rate of the silicon, oxygen, and nitrogen-containing film 12′ above the zones Z1 and Z3 is increased. Thereby, the silicon, oxygen, and nitrogen-containing film 12′ formed on the substrate 10 has a uniform thickness.

In some embodiments, the plasma includes negatively ionized gases, and the variable voltage sources 224 and 228 provide a negative voltage to the second and the fourth electrodes 210b and 210d to repel the negatively ionized gases away from the portions of the substrate 10 above the zones Z2 and Z4. Therefore, the deposition rate of the silicon, oxygen, and nitrogen-containing film 12′ above the zones Z2 and Z4 is decreased. Thereby, a silicon, oxygen, and nitrogen-containing film 12′ formed on the substrate 10 has a uniform thickness.

In some embodiments, the plasma includes negatively ionized gases. The variable voltage sources 224 and 228 may provide a negative voltage to the second and the fourth electrodes 210b and 210d, and the variable voltage sources 222 and 226 may provide a positive voltage to the first and the third electrodes 210a and 210c according to requirements.

In some embodiments, the two adjacent electrodes (e.g 222 and 224, 224 and 226, or 226 and 228) are simultaneously provided with different voltages according to requirements. In some other embodiments, the two adjacent electrodes (e.g 222 and 224, 224 and 226, or 226 and 228) are simultaneously provided with the same voltages according to requirements.

As shown in FIG. 2C, the electrodes 210a, 210b, 210c and 210d have widths (or line widths) W1, W2, W3 and W4, respectively. In some embodiments, each of the width W1, W2, W3 and W4 ranges from about 30 mm to about 50 mm. In some embodiments, each of the width W1, W2, W3 and W4 ranges from about 50 mm to about 70 mm. In some embodiments, the widths W1, W2, W3 and W4 are the same. In some other embodiments, some or all of the widths W1, W2, W3 and W4 are different.

Spacings S1, S2 and S3 are between the electrodes 210a, 210b, 210c and 210d, respectively. Each of the spacings S1, S2 and S3 may range from about 1 mm to about 5 mm. In some embodiments, the spacings S1, S2 and S3 are the same. In some other embodiments, some or all of the spacings S1, S2 and S3 are different.

After the silicon, oxygen, and nitrogen-containing film 12′ is formed, the silicon, oxygen, and nitrogen-containing film 12′ is converted into a silicon oxide film 12a′, as shown in FIG. 2D, in accordance with some embodiments. The conversion process may include curing the silicon, oxygen, and nitrogen-containing film 12′ in an oxygen-containing atmosphere and annealing the silicon, oxygen, and nitrogen-containing film 12′ in an oxygen-containing atmosphere. The silicon oxide film 12a′ may be planarized into a planarized silicon oxide film 12b′ (as shown in FIG. 2E) by using, for example, a chemical-mechanical polishing (CMP) process.

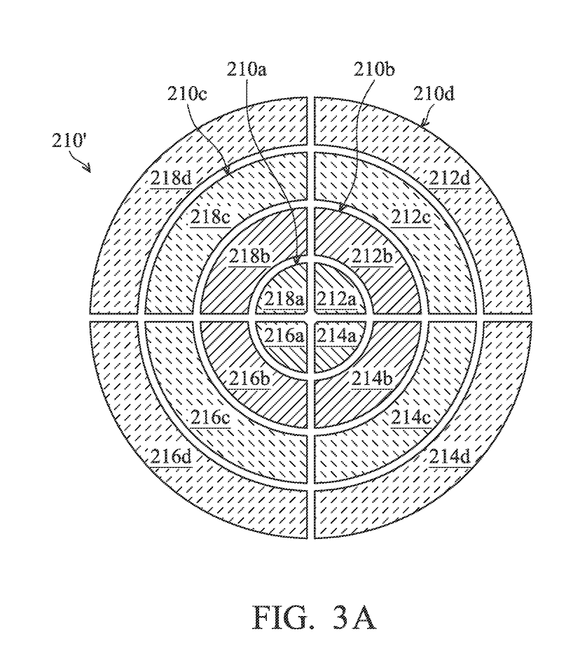

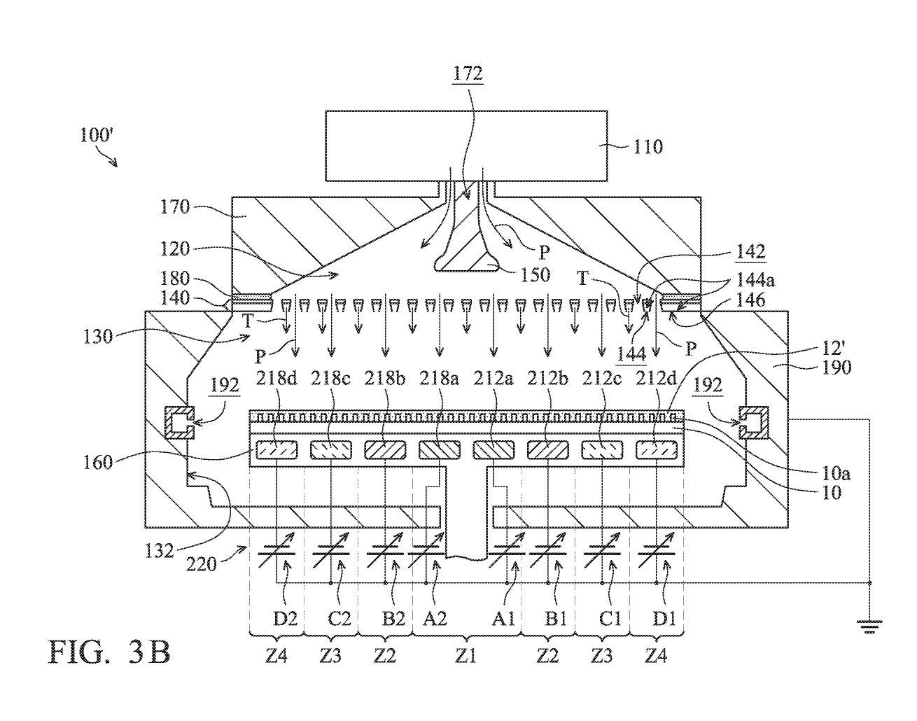

In some other embodiments, the first electrode 210a, the second electrode 210b, the third electrode 210c and the fourth electrode 210d may be discontinuous ring structures, as shown in FIG. 3A. The first electrode 210a may have parts 212a, 214a, 216a and 218a separated from each other and arranged in a ring shape. The second electrode 210b may have parts 212b, 214b, 216b and 218b separated from each other and arranged in a ring shape. The third electrode 210c may have parts 212c, 214c, 216c and 218c separated from each other and arranged in a ring shape. The fourth electrode 210d may have parts 212d, 214d, 216d and 218d separated from each other and arranged in a ring shape.

FIG. 3B is a cross-sectional view of a film deposition tool with the electrodes 210′ of FIG. 3A, in accordance with some embodiments. In some embodiments, the parts 212a, 214a, 216a, 218a, 212b, 214b, 216b, 218b, 212c, 214c, 216c, 218c, 212d, 214d, 216d and 218d may be coupled to different variable voltage sources and may be provided with voltages independently. As shown in FIGS. 3A and 3B, the parts 212a, 218a, 212b, 218b, 212c, 218c, 212d, and 218d may be coupled to the variable voltage sources A1, A2, B1, B2, C1, C2, D1 and D2, respectively. In some embodiments, as shown in FIG. 3B, the parts 212a and 218a are under the diffuser 150.

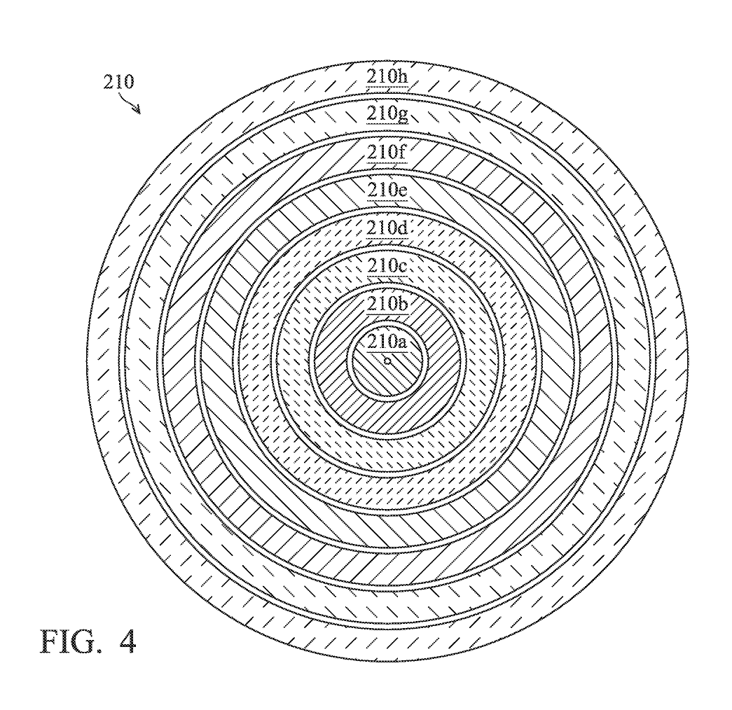

It should be noted that the number of electrodes 210 (as shown in FIG. 2C) is not limited to four, but can be any other suitable number larger than one. For example, as shown in FIG. 4, the number of electrodes 210 is eight. The electrodes 210 include electrodes 210a, 210b, 210c, 210d, 210e, 210f, 210g and 210h.

Embodiments of mechanisms for depositing a substantially uniform film on a substrate are provided. By applying different bias voltages to different portions of the substrate during a depositing process using a plasma, the depositing process is controlled. Thereby, a film with a uniform thickness is formed, which avoids the stress issue in the subsequent processes (e.g. the annealing process and the CMP process). Therefore, the yield is improved.

In accordance with some embodiments, a film deposition tool is provided. The film deposition tool includes a plasma source and a substrate processing region connected to the plasma source. The film deposition tool also includes a pedestal for supporting a substrate in the substrate processing region, wherein the substrate is prepared to be deposited with a film. The film deposition tool further includes electrodes embedded in the pedestal and separated from each other. The film deposition tool also includes a direct current bias system having variable voltage sources. The variable voltage sources are electrically connected to the electrodes, respectively, for providing direct current voltages to the electrodes independently.

In accordance with some embodiments, a film deposition tool is provided. The film deposition tool includes a plasma source and a substrate processing region connected to the plasma source. The film deposition tool also includes a pedestal for supporting a substrate in the substrate processing region, wherein the substrate is prepared to be deposited with a film. The film deposition tool further includes electrodes embedded in the pedestal and separated from each other. Each of the electrodes has parts separated from each other and arranged in a ring shape. The film deposition tool also includes a direct current bias system having variable voltage sources. The variable voltage sources are electrically connected to the parts of the electrodes, respectively, for providing direct current voltages to the parts independently.

In accordance with some embodiments, a method for forming a film is provided. The method includes providing a substrate onto a pedestal in a substrate processing region, wherein electrodes are embedded in the pedestal and are separated from each other. The method also includes providing a plasma and a precursor into the substrate processing region to form a film on the substrate. During the formation of the film, different bias voltages are applied to different portions of the substrate above the different electrodes.

Although the embodiments and their advantages have been described in detail, it should be understood that various changes, substitutions, and alterations can be made herein without departing from the spirit and scope of the embodiments as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

1. A film deposition tool, comprising:
a plasma source;
a substrate processing region connected to the plasma source;
a pedestal for supporting a substrate in the substrate processing region, wherein the substrate is prepared to be deposited with a film;
a plurality of electrodes embedded in the pedestal and separated from each other; and
a direct current bias system having a plurality of variable voltage sources, wherein the variable voltage sources are electrically connected to the electrodes, respectively, for providing direct current voltages to the electrodes independently.

2. The film deposition tool as claimed in claim 1, further comprising:
a chamber plasma region above the substrate processing region and connected to the plasma source; and
a showerhead between the chamber plasma region and the substrate processing region, wherein the showerhead has a plurality of through holes and a hollow volume separated from the through holes, and the hollow volume has holes connected to the substrate processing region.

3. The film deposition tool as claimed in claim 2, wherein the plasma source is connected to an inlet opening of the chamber plasma region, and the film deposition tool further comprises:
a diffuser disposed in the chamber plasma region and close to the inlet opening to diffuse the plasma from the plasma source.

4. The film deposition tool as claimed in claim 3, wherein at least one of the electrodes is under the diffuser.

5. The film deposition tool as claimed in claim 1, wherein the electrodes are in a ring shape.

6. The film deposition tool as claimed in claim 5, wherein one of the electrodes surrounds another one of the electrodes.

7. The film deposition tool as claimed in claim 5, wherein the number of the electrodes ranges from 4 to 8.

8. The film deposition tool as claimed in claim 1, wherein at least one of the electrodes is a continuous ring structure.

9. The film deposition tool as claimed in claim 1, wherein the film deposition tool comprises a flowable chemical vapor deposition tool.

10. The film deposition tool as claimed in claim 1, wherein the plasma source comprises a remote plasma system.

11. The film deposition tool as claimed in claim 1, wherein the direct current bias system and a chamber wall surrounding the substrate processing region are grounded together.

12. A film deposition tool, comprising:
a plasma source;
a substrate processing region connected to the plasma source;
a pedestal for supporting a substrate in the substrate processing region, wherein the substrate is prepared to be deposited with a film;
a plurality of electrodes embedded in the pedestal and separated from each other, wherein each of the electrodes has a plurality of parts separated from each other and arranged in a ring shape; and
a direct current bias system having a plurality of variable voltage sources, wherein the variable voltage sources are electrically connected to the parts of the electrodes, respectively, for providing direct current voltages to the parts independently.

13. The film deposition tool as claimed in claim 12, further comprising:
a chamber plasma region above the substrate processing region and connected to the plasma source; and
a showerhead between the chamber plasma region and the substrate processing region, wherein the showerhead has a plurality of through holes and a hollow volume separated from the through holes, and the hollow volume has holes connected to the substrate processing region.

14. The film deposition tool as claimed in claim 12, wherein the plasma source is connected to an inlet opening of the chamber plasma region, and the film deposition tool further comprises:
a diffuser disposed in the chamber plasma region and close to the inlet opening to diffuse the plasma from the plasma source, wherein at least one of the parts of the electrodes is under the diffuser.

15-20. (canceled)

21. The film deposition tool as claimed in claim 6, wherein the electrodes are arranged in a series of concentric rings.

22. The film deposition tool as claimed in claim 12, wherein one of the electrodes surrounds another one of the electrodes.

23. The film deposition tool as claimed in claim 12, wherein the number of the electrodes ranges from 4 to 8.

24. The film deposition tool as claimed in claim 12, wherein the film deposition tool comprises a flowable chemical vapor deposition tool.

25. The film deposition tool as claimed in claim 12, wherein the plasma source comprises a remote plasma system.

26. The film deposition tool as claimed in claim 12, wherein the direct current bias system and a chamber wall surrounding the substrate processing region are grounded together.
